(19) United States
(12) Patent Application Publication
(10) Pub. No.: US 2008/0048193 A1
(43) Pub. Date: Feb. 28, 2008

(54) White light emitting diode module

(75) Inventors: Chul Hee Yoo, Gyunggi-do (KR); Il Ku Kim, Gyunggi-do (KR); Seong Yeon Han, Gwangju (KR); Hyung Suk Kim, Gyunggi-do (KR); Hun Joo Hahm, Gyunggi-do (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/819,568

(22) Filed: Jun. 28, 2007

(30) Foreign Application Priority Data
Aug. 25, 2006 (KR) 10-2006-0081151

(51) Int. Cl. H01L 33/00

(52) U.S. Cl. 257/89; 257/98; 257/E33.061; 257/E33.056

(57) ABSTRACT

A white LED module includes a circuit board, a blue LED chip disposed on the circuit board, a green light source of an LED chip or phosphor disposed on the circuit board, and a red light source of an LED chip or phosphor disposed on the circuit board. At least one of the green and red light sources is a phosphor, which is excited by the blue LED chip to radiate. The blue LED chip emits light in a triangular region defined by color coordinates (0.0123, 0.5346), (0.0676, 0.4633) and (0.17319, 0.0048), the green light source emits light in a triangular region defined by color coordinates (0.025, 0.5203), (0.4479, 0.541) and (0.0722, 0.7894), and the red light source emits light in a triangular region defined by color coordinates (0.556, 0.4408), (0.6253, 0.3741) and (0.7346, 0.2654).

### CLAIM OF PRIORITY

This application claims the benefit of Korean Patent Application No. 2006-0081151 filed on Aug. 25, 2006, in the Korean Intellectual Property Office, the disclosure of which is incorporated herein by reference.

### BACKGROUND OF THE INVENTION

1. Field of the Invention

The present invention relates to a white Light Emitting Diode (LED) module and, more particularly, to a white LED module which has superior color uniformity and color reproducibility and can be easily manufactured with reduced manufacturing costs.

2. Description of the Related Art

With recent trend of miniaturization and high functionality of image display devices, Liquid Crystal Displays (LCDs) are extensively used for televisions and monitors. The LCD cannot emit light on its own, and thus requires a separate light source unit called a Backlight Unit (BLU). Cold Cathode Fluorescent Lamps (CCFLs) have been used conventionally as a white light source for the BLU, but “white light source modules (hereinafter, ‘LED modules’)” have been attracting interest since they are advantageous in terms of color expression and power consumption.

The conventional white LED module for BLU is realized by arranging blue, green and red LEDs on a circuit board. Such an example is illustrated in FIG. 1. As shown, the white LED module 10 includes a blue B, green G, red R LED chips 14, 16 and 18 arranged on a circuit board 11 such as a PCB. The LED chips 14, 16 and 18 are mounted in respective package bodies 13, 15 and 17 mounted on the circuit board 11. The R, G and B LED packages can be arranged repeatedly on the board. The white LED module 10 using the R, G and B of three primary color LED chips has superior color reproducibility and enables total output light control by adjusting the light amounts of blue, green and red LEDs.

However, according to the white LED module 10 described above, the R, G and B light sources (LEDs) are apart from each other, hindering color uniformity. In addition, since at least three of R, G and B LED chips are required to obtain a unit region of white light, the configuration of a circuit has a complicated configuration for driving and controlling individual color LEDs (increasing the costs for the circuit), thereby increasing the manufacturing costs for the package.

There has been suggested an alternative way of realizing a white LED module, which is using a blue B LED chip and a yellow Y phosphor excited by the blue LED chip. Such combination of “a blue LED and yellow phosphor” has advantages like simple configuration of a circuit and low costs, but does not have excellent color reproducibility due to low light intensity in a long wavelength range. Therefore, there is required a white LED module of low costs and high quality which can output optimal white light with superior color reproducibility and color uniformity.

### SUMMARY OF THE INVENTION

The present invention has been made to solve the foregoing problems of the prior art and therefore an aspect of the present invention is to provide a white LED module which not only outputs optimal white light with superior color uniformity and color reproducibility, but also incurs relatively low manufacturing costs.

According to an aspect of the invention, the invention provides a white Light LED module which includes a circuit board; a blue LED chip disposed on the circuit board; a green light source disposed on the circuit board and composed of an LED chip or a phosphor; and a red light source disposed on the circuit board and composed of an LED chip or a phosphor, wherein at least one of the green light source and the red light source composed of a phosphor, which is excited by the blue LED chip to radiate, wherein the blue LED chip, the green light source and the red light source emit light beams that are mixed together to produce white light, and wherein the blue LED chip emits the light beam in a triangular region defined by color coordinates (0.0123, 0.5346), (0.0676, 0.4633) and (0.17319, 0.0048) based on CIE 1931, the green light source emits the light beam in a triangular region defined by color coordinates (0.025, 0.5203), (0.4479, 0.541) and (0.0722, 0.7894) based on CIE 1931, and the red light source emits the light beam in a triangular region defined by color coordinates (0.556, 0.4408), (0.6253, 0.3741) and (0.7346, 0.2654) based on CIE 1931.

Each of the LED chips may be directly mounted on the circuit board or can be mounted in a reflector cup of at least one package body. In the case of using a red phosphor as the red light source, it is preferable that the red light source is a nitride-based red phosphor.

According to a first aspect of the invention, the green light source can be a green LED chip, and the red light source can be a red phosphor. According to an embodiment of the present invention, the blue and green LED chips are mounted directly on the circuit board, and a resin encapsulant can encapsulate both of the blue and green LED chips.

According to another embodiment of the present invention, the blue and green LED chips can be mounted directly on the circuit board, and a resin encapsulant containing the red phosphor can encapsulate only the blue LED chip.

According to further another embodiment of the present invention, the white LED module further includes at least one package body with a reflector cup disposed on the circuit board, wherein the blue and green LED chips are mounted in the reflector cup of the at least one package body.

In addition, the blue and green LED chips can be mounted together in the reflector cup of the at least one package body, and a resin encapsulant containing the red phosphor can encapsulate both of the blue and green LED chips. Alternatively, each of the blue and green LED chips can be mounted separately in the reflector cup of each of the package bodies, and a resin encapsulant containing the red phosphor can encapsulate the blue LED chip.

According to a second aspect of the present invention, the green light source can be a green phosphor and the red light source comprises a red LED chip. According to an embodiment of the present invention, the blue and red LED chips can be mounted directly on the circuit board, and a resin encapsulant containing the green phosphor can encapsulate both of the blue and red LED chips.

According to further another embodiment of the present invention, the blue and red LED chips can be mounted directly on the circuit board, and a resin encapsulant containing the green phosphor can encapsulate only the blue LED chip.

According to further another embodiment of the present invention, the white LED module may further include at least one package body with a reflector cup disposed on the circuit board, wherein the blue and red LED chips are mounted in the reflector cup of the at least one package body.

The blue and red LED chips can be mounted together in the reflector cup of the package body, and a resin encapsulant containing the green phosphor can encapsulate both of the blue and red LED chips. Alternatively, each of the blue and red LED chips can be separately mounted in the reflector cup of each of the package bodies, and a resin encapsulant containing the green phosphor can encapsulate the blue LED chip.

According to a third aspect of the present invention, the green light source can be a green phosphor and the red light source can be a red phosphor. According to an embodiment of the present invention, the blue LED chip can be mounted directly on the circuit board, and a resin encapsulant containing the red and green phosphors can encapsulate the blue LED chip.

According to another embodiment of the present invention, the white LED module further includes a package body with a reflector cup mounted on the circuit board, wherein the blue LED chip is mounted in the reflector cup of the package body, and a resin encapsulant containing the green and red phosphors can encapsulate the blue LED chip.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a sectional view illustrating a conventional white LED module for a backlight unit;

FIG. 2 is a sectional view illustrating a white LED module according to an embodiment of the present invention;

FIG. 3 is a sectional view illustrating a white LED module according to another embodiment of the present invention;

FIG. 4 is a sectional view illustrating a white LED module according to further another embodiment of the present invention;

FIG. 5 is a sectional view illustrating a white LED module according to further another embodiment of the present invention;

FIG. 6 is a sectional view illustrating a white LED module according to further another embodiment of the present invention;

FIG. 7 is a sectional view illustrating a white LED module according to further another embodiment of the present invention;

FIG. 8 is a sectional view illustrating a white LED module according to further another embodiment of the present invention; and

FIG. 9 is a sectional view illustrating a white LED module according to yet another embodiment of the present invention.

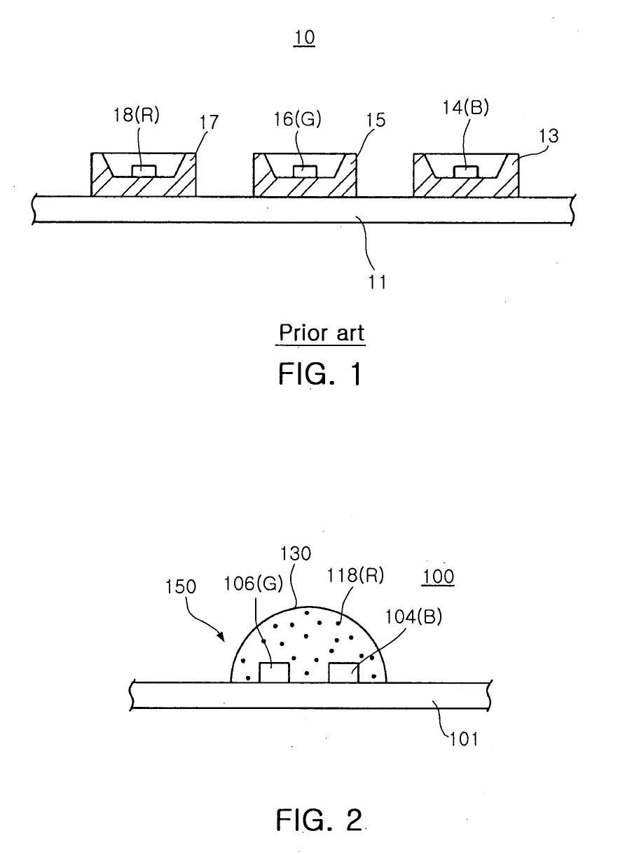

### DETAILED DESCRIPTION OF THE PREFERRED EMBODIMENT

Exemplary embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity and the same or like components are designated by the same reference numerals.

FIG. 2 is a sectional view illustrating a white LED module according to an embodiment of the present invention.

Referring to FIG. 2, the white LED module 100 includes a circuit board 101 such as a PCB and a blue LED chip 104, a green G LED chip 106 and a red R phosphor 118 disposed on the circuit board. In particular, in this embodiment, the LED chips 104 and 106 are directly mounted on the circuit board 101. An upper hemispheric resin encapsulant 130 for encapsulating the blue and green LED chips 104 and 106 contains the red phosphor 118. The resin encapsulant 130 not only protects the LED chips 104 and 106 as well as their connection parts, but also functions as a lens. Adopting such Chip-On-Board method allows easily obtaining a larger beam angle from each of the LED light sources. A white light source unit 150 for a unit region, composed of the blue and green LED chips 104 and 106 and the red phosphor 118, can be repeated on the circuit board 101 to form a desired area of surface light source or a line light source.

During the operation of the white LED module 100, the blue LED chip 104 and the green LED chip 106 emit blue light and green light, respectively. The blue LED chip 104 can have a wavelength range of 370 to 470 nm. The red phosphor 118 is excited mainly by the light emitted from the blue LED chip 104 to produce red light. Preferably, the red phosphor is a nitride-based phosphor. The nitride phosphor has excellent reliability with respect to external environment such as heat and moisture and has less likelihood of discoloration, as compared to the existing sulfide-based phosphor.

White light is produced by the mixture of the blue light and green light emitted by the blue and green LED chips 104 and 106 and the red light emitted by the red phosphor 118. In order to output white light with optimal color reproducibility, the blue light source (the blue LED chip 104), the green light source (the green LED chip 106) and the red light source (the red phosphor 118) emit light in particular triangular regions defined by color coordinates based on CIE 1931 (standard calorimetric system 1931), respectively.

Specifically, the blue LED chip 104 emits light in a triangular region defined by color coordinates (0.0123, 0.5346), (0.0676, 0.4633) and (0.17319, 0.0048) based on the CIE 1931. The green LED chip 106 emits light in a triangular region defined by (0.025, 0.5203), (0.4479, 0.541) and (0.0722, 0.7894) based on the color coordinates. The red phosphor 118 emits light in a triangular region defined by color coordinates (0.556, 0.4408), (0.6253, 0.3741) and (0.7346, 0.2654) based on the CIE 1931. The three primary colors in these triangular regions are mixed to achieve optimal white light with superior color reproducibility, close to natural light.

According to the white LED module 100 described above, compared to the conventional white LED module using R, G and B LED chips, the number of required LED chips is reduced and the types of LED chips is reduced to two (blue and green LED chips). This reduces the manufacturing costs and simplifies a configuration of a driving circuit. In addition, a unit region of white light is realized by only two LED chips and the phosphor placed over these two LED chips, allowing superior color uniformity compared to the conventional case of using R, G and B LED chips. Furthermore, the white LED module 100 allows sufficient intensity in a long wavelength range through the green LED chip 106 and the red phosphor 118, significantly improving color reproducibility compared to the conventional white LED module of the combination of “blue LED chip and yellow phosphor.”

In particular, using the blue and green LED chips with the red phosphor to produce white light as described above effectively prevents degradation of entire color uniformity due to the thermal deterioration of the red LED chip. Since the red LED chip is vulnerable to heat compared to the blue or green LED chip, the light efficiency of the red LED chip is significantly degraded after a predetermined period of use compared to other LED chips. Therefore, in the case of using the R, G and B LED chips to produce a unit region of white light, the color uniformity is significantly low due to the low light efficiency of the red LED chip by the heat generated during the use. However, in this embodiment, the red phosphor (particularly, a nitride-based red phosphor) is used instead of a red LED chip, preventing the degradation of color uniformity due to the heat.

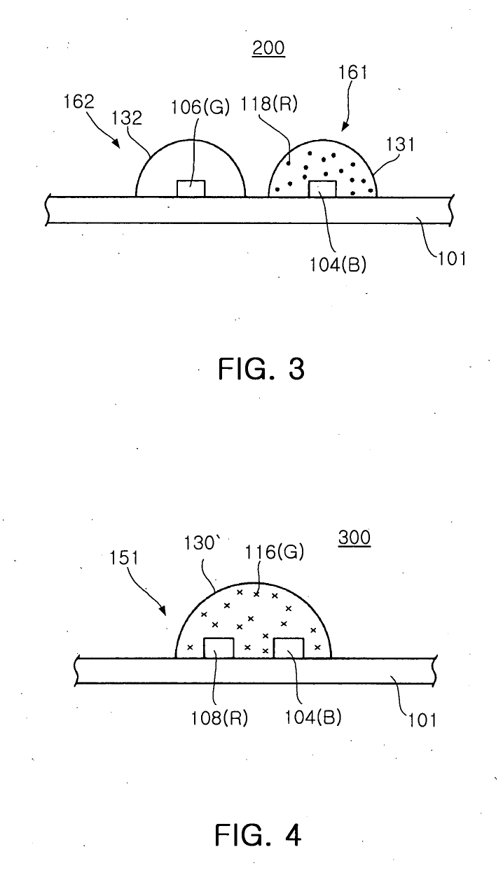

FIG. 3 is a sectional view schematically illustrating a white LED module 200 according to another embodiment of the present invention. Referring to FIG. 3, unlike in the aforedescribed embodiment (see FIG. 2), separated resin encapsulants 131 and 132 encapsulate a blue LED chip 104 and a green LED chip 106, respectively. That is, the resin encapsulant 131 containing a red phosphor 119 encapsulates only the blue LED chip 104, and the transparent resin encapsulant 132 (not containing the phosphor) encapsulates the green LED chip 106. The white LED module 200 has an identical configuration as the white LED module 100 described with reference to FIG. 2, except for the resin encapsulants separately encapsulating the chips.

The red phosphor 118 is excited by the light emitted from the blue LED chip 104 to emit red light. White light is produced by the blue light and green light emitted from the blue and green LED chips 104 and 106 and the red light emitted from the red phosphor. A first light source unit 161 of “the blue LED chip and red phosphor” and a second light source unit 162 of “the green LED chip” are repeatedly arranged on the board 101 to form a desired area of surface light source or line light source.

Like in the aforedescribed embodiment, the white LED module 200 produces three primary colors in the above described triangular regions on the CIE chromaticity coordinates, and exhibits sufficient light intensity in a long wavelength range, thereby outputting optimal white light with superior color reproducibility. In addition, this allows reducing the number of required LED chips and manufacturing costs of the package, simplifies the configuration of the driving circuit, and allows superior color uniformity. Furthermore, the red phosphor is used instead of a red LED chip, preventing the degradation of color uniformity by the heat during the use.

FIG. 4 is a sectional view schematically illustrating a white LED module according to further another embodiment of the present invention. In this embodiment, a green phosphor 116 is used instead of a green LED chip, and a red LED chip 108 is used instead of a red phosphor.

Referring to FIG. 4, a blue LED chip 104 and the red LED chip 108 are mounted directly on the circuit board 101. In addition, an upper hemispheric resin encapsulant 130′ containing the green phosphor 116 encapsulates both of the blue and red LED chips 104 and 108. The green phosphor 116 is excited by the blue LED chip 104 to emit green light. In order to obtain a desired area of surface light source or line light source, a light source unit 151 of “the blue and red LED chips and the green phosphor” can be repeated on the board 101.

White light is produced by the mixture of blue, green and red light beams emitted from the three primary colors of light sources 104, 116 and 108. In order to output optimal white light with superior color reproducibility, the blue LED chip 104, the green phosphor 116 and the red LED chip 118 emit light in the aforementioned particular triangular regions based on the CIE 1931 chromaticity coordinates.

That is, the blue LED chip 104 emits light in a triangular region defined by the color coordinates (0.0123, 0.5346), (0.0676, 0.4633) and (0.17319, 0.0048) based on CIE 1931, and the red LED chip 108 emits light in a triangular region defined by color coordinates (0.556, 0.4408), (0.6253, 0.3741) and (0.7346, 0.2654) based on the CIE 1931. In addition, the green phosphor 116 emits light in a triangular region defined by color coordinates (0.025, 0.5203), (0.4479, 0.541) and (0.0722, 0.7894) based on the CIE 1931. The mixture of the three primary colors in the triangular regions allows optimal white light with superior color reproducibility, close to natural light.

According to the white LED module 300, compared to the conventional white LED module using R, G and B LED chips, the number of required LED chips is reduced and the types of the LED chips is reduced to two (blue and red LED chips). This reduces the manufacturing costs of the package and simplifies the configuration of the driving circuit. In addition, since a unit region of white light is realized by only the two LED chips and the phosphor placed over these two LED chips, thus allowing superior color uniformity to the conventional case of using R, G and B LED chips. Furthermore, the white LED module 300 achieves sufficient intensity in a long wavelength range with the red LED chip 108 and the green phosphor 116, significantly improving color reproducibility compared to the conventional white LED module of the combination of “blue LED chip and yellow phosphor.”

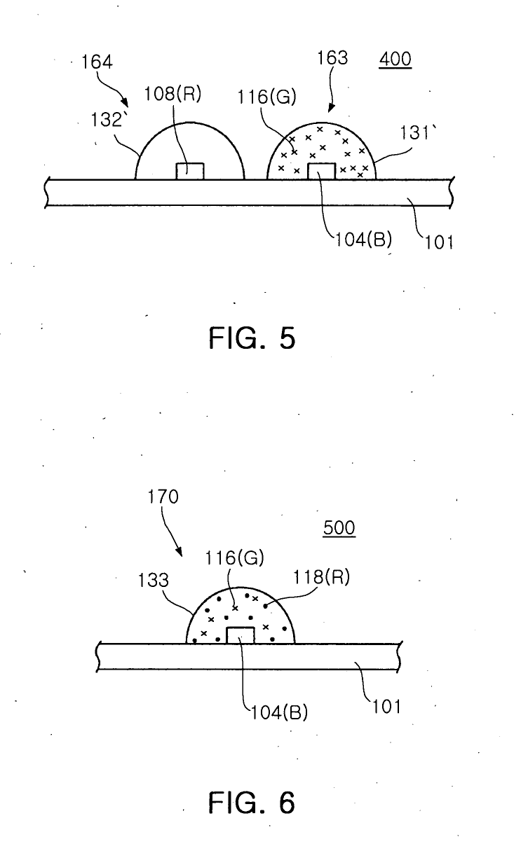

FIG. 5 is a sectional view schematically illustrating a white LED module according to further another embodiment of the present invention. Referring to FIG. 5, unlike in the embodiment of FIG. 4, separated resin encapsulants 131′ and 132′ encapsulate the blue LED chip 104 and the red LED chip 108, respectively. That is, the resin encapsulant 131′ containing a green phosphor 116 encapsulates only the blue LED chip 104, and the transparent encapsulant 132′ (not containing the phosphor) encapsulates the red LED chip 108. The white LED module 400 has an identical configuration as the white LED module 300 of FIG. 4, except for the resin encapsulants separately encapsulating the chips.

The green phosphor 116 is excited by the light emitted from the blue LED chip 104 to emit green light. White light is produced by the mixture of the blue light and red light from the blue and red LED chips 104 and 108 and the green light from the green phosphor. A first light source unit 163 of “the blue LED chip and green phosphor” and a second light source unit 164 of “the red LED chip” are repeated on the board 101 to form a desired area of surface light source or line light source.

Like in the aforedescribed embodiments, the white LED module 400 emits three primary colors in the aforementioned triangular regions on the CIE chromaticity coordinates, and exhibits sufficient light intensity in a long wavelength range, thereby outputting optimal white light with superior color reproducibility. In addition, this reduces the number of required LED chips and manufacturing costs of the package, simplifies the configuration of the driving circuit, and allows superior color uniformity.

FIG. 6 is a sectional view schematically illustrating a white LED module according to further another embodiment of the present invention. Referring to FIG. 6, the white LED module 500 includes a blue LED chip 104, a green phosphor 116 and a red phosphor 118 disposed on a circuit board 101. The blue LED chip 104 is mounted directly on the board 101, and an upper hemispheric resin encapsulant 133 containing the green and red phosphors 116 and 118 encapsulates the blue LED chip 104. Using such a chip-on-board LED module allows a large beam angle from the LED light source. In order to obtain a desired area of surface light source or line light source, a light source unit 170 of “the blue LED chip 104 and the green and red phosphors 116 and 118 can be repeated on the board 101.

The green and red phosphors 116 and 118 contained in the resin encapsulant 133 are excited by the blue LED chip 104 to emit green light and red light, respectively. White light is produced by the mixture of the green light and red light from the phosphors and the blue light (from the blue LED chip). Like in the aforedescribed embodiments, in order to output optimal white light with superior color reproducibility, the three primary colors of light sources 104, 116 and 118 emit light in the aforementioned triangular regions on the chromaticity coordinates.

That is, the blue LED chip 104 emits light in a triangular region defined by color coordinates (0.0123, 0.5346), (0.0676, 0.4633) and (0.17319, 0.0048) based on CIE 1931. The green phosphor 116 emits light in a triangular region defined by color coordinates (0.025, 0.5203), (0.4479, 0.541) and (0.0722, 0.7894) based on the CIE 1931, and the red phosphor 118 emits light in a triangular region defined by color coordinates (0.556, 0.4408), (0.6253, 0.3741) and (0.7346, 0.2654) based on the CIE 1931.

According to the white LED module 500, compared to the conventional LED module using R, G and B LED chips, the number of required LED chips is reduced and the types of the LED chips is reduced to one (blue LED chip). This allows significantly reducing the manufacturing costs of the package and simplifies the configuration of the driving circuit. In addition, a unit region of white light is realized by only one LED chip and a mixture of the phosphors encapsulating the chip, thus allowing superior color uniformity compared to the convention case of using R, G and B LED chips. Moreover, the white LED module 500 exhibits sufficient intensity in a long wavelength range with the red phosphor 118 and the green phosphor 116, significantly improving color reproducibility compared to the conventional LED module of the combination of “a blue LED chip and yellow phosphor.” Furthermore, using the red phosphor instead of the red LED chip improves the problematic degradation of light efficiency of the red LED chip by the heat and resultant degradation of entire color uniformity.

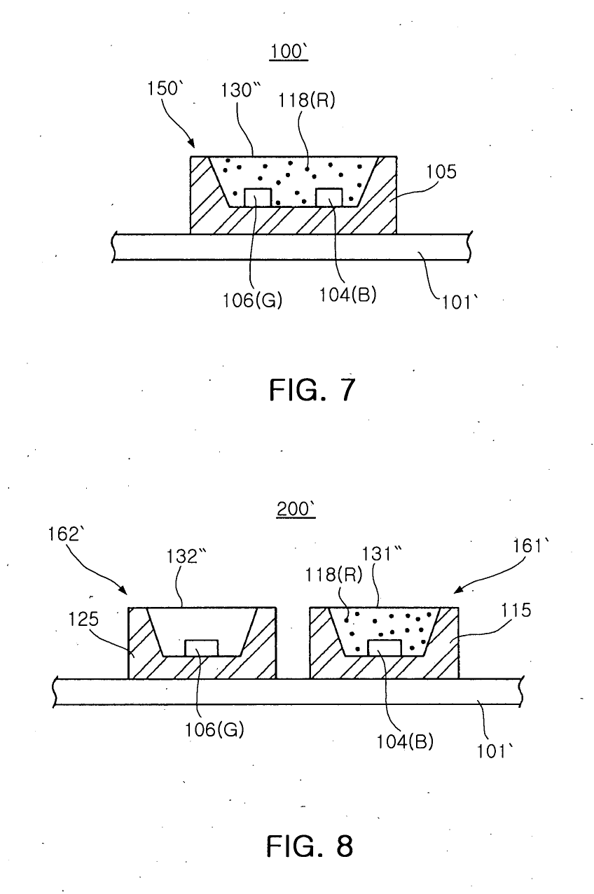

In the aforedescribed embodiments set forth above, each of the LED chips is mounted directly on the circuit board, but the present invention is not limited to such. For example, the LED chip can be mounted in a package body mounted on the circuit board. The embodiments using separate package bodies are shown in FIGS. 7 to 9.

Referring to FIG. 7, like in the embodiment shown in FIG. 2, the white LED module 100′ includes blue and green LED chips and a red phosphor 118. A package boy 105 having a recessed reflector cup is mounted on the circuit board 101′. The blue LED chip 104 and the green LED chip 106 are mounted together in the reflector cup of the package body 105, and a resin encapsulant 130″ containing the red phosphor 118 encapsulates both of the blue and green LED chips 104 and 106. In order to obtain a desired area of surface light source or line light source, a blue LED package 150′ including “the blue and green LED chips 104 and 106 and red phosphor 118” can be repeated on the board 101′.

Referring to FIG. 8, similar to the embodiment shown in FIG. 3, the white LED module 200′ includes separated LED light sources or packages 161′ and 162′. A blue LED chip 104 is mounted in a reflector cup of a package body 115, and a green LED chip 106 is mounted in a reflector cup of another package body 125. A resin encapsulant 131″ containing the red phosphor 118 encapsulates the blue LED chip 104, and a transparent resin encapsulant 132″ (not containing the phosphor) encapsulates the green LED chip 106. In order to obtain a desired area of surface light source or line light source, the LED package 161′ containing “the blue LED chip 104 and red phosphor 118” and the LED package 162′ containing “the green LED chip 106” can be repeated on the board 101′.

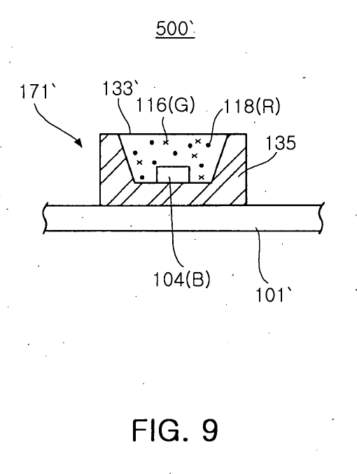

FIG. 9 is a sectional view illustrating a white LED module 500′ according to further another embodiment of the present invention. Referring to FIG. 9, like in the embodiment shown in FIG. 6, the white LED module 500′ includes a blue LED chip 104, a green phosphor 116 and a red phosphor 118. A package body 135 having a reflector cup is disposed on the board 101′, and the blue LED chip 104 is mounted in the reflector cup of the package body 135. A resin encapsulant 133′ containing the green and red phosphors 116 and 118 encapsulates the blue LED chip 104. In order to obtain a desired area of surface light source and line light source, an LED package 171′ including “the blue LED chip 104 and the green and red phosphors 116 and 118” can be repeated on the board 101′.

Like in the embodiments shown in FIGS. 2, 3 and 6, the white LED modules 100′, 200′ and 500′ output optimal white light with superior color reproducibility. In addition, the white LED modules reduce the number of required LED chips and manufacturing costs of the package, simplify the configuration of the driving circuit, and allow excellent color uniformity. In particular, using the red phosphor instead of the red LED chip prevents the problematic degradation of color uniformity by the heat during the use.

In addition to the exemplary embodiments shown in FIGS. 7 to 9, blue and red LED chips with a green phosphor can form an LED package. For example, in the configurations of the white LED modules 100′ and 200′ shown in FIGS. 7 and 8, a red LED chip 108 can replace the green LED chip 106, and green phosphor 116 can replace the red phosphor 118.

According to the present invention as set forth above, a white LED module produces optimal white light with superior color reproducibility. In addition, the white LED module reduces the number of required LED chips and the manufacturing costs of the package, simplifies the configuration of the driving circuit, and allows superior color uniformity. Furthermore, using a red phosphor instead of a red LED chip prevents degradation of light efficiency of the red LED chip by the heat and resultant degradation of entire color uniformity. In particular, the white LED module ensures good color uniformity even during long hours of use.

While the present invention has been shown and described in connection with the exemplary embodiments, it will be apparent to those skilled in the art that modifications and variations can be made without departing from the spirit and scope of the invention as defined by the appended claims.

What is claimed is:

1. A white Light Emitting Diode (LED) module comprising:
a circuit board;
a blue LED chip disposed on the circuit board;
a green light source disposed on the circuit board and comprising an LED chip or a phosphor; and
a red light source disposed on the circuit board and comprising an LED chip or a phosphor,
wherein at least one of the green light source and the red light source comprises a phosphor, the phosphor being excited by the blue LED chip to radiate,
wherein the blue LED chip, the green light source and the red light source emit light beams that are mixed together to produce white light, and
wherein the blue LED chip emits the light beam in a triangular region defined by color coordinates (0.0123, 0.5346), (0.0676, 0.4633) and (0.17319, 0.0048) based on CIE 1931, the green light source emits the light beam in a triangular region defined by color coordinates (0.025, 0.5203), (0.4479, 0.541) and (0.0722, 0.7894) based on CIE 1931, and the red light source emits the light beam in a triangular region defined by color coordinates (0.556, 0.4408), (0.6253, 0.3741) and (0.7346, 0.2654) based on CIE 1931.

2. The white LED module according to claim 1, wherein each of the LED chips is directly mounted on the circuit board.

3. The white LED module according to claim 1, further comprising at least one package body with a reflector cup disposed on the board, wherein each of the LED chips is mounted in the reflector cup of the at least one package body.

4. The white LED module according to claim 1, wherein the red light source comprises a nitride-based red phosphor.

5. The white LED module according to claim 1, the green light source comprises a green LED chip, and the red light source comprises a red phosphor.

6. The white LED module according to claim 5, wherein the blue and green LED chips are mounted directly on the circuit board, and
wherein the white LED module further comprising a resin encapsulant for encapsulating both of the blue and green LED chips.

7. The white LED module according to claim 5, wherein the blue and green LED chips are mounted directly on the circuit board, and
wherein the white LED module further comprising a resin encapsulant containing the red phosphor for encapsulating only the blue LED chip.

8. The white LED module according to claim 5, further comprising at least one package body with a reflector cup disposed on the circuit board, wherein the blue and green LED chips are mounted in the reflector cup of the at least one package body.

9. The white LED module according to claim 8, wherein the blue and green LED chips are mounted together in the reflector cup of the at least one package body, and
wherein the white LED module further comprising a resin encapsulant containing the red phosphor for encapsulating both of the blue and green LED chips.

10. The white LED module according to claim 8, wherein the at least one package body comprises two package bodies with each of the blue and green LED chips mounted separately in the reflector cup of each of the package bodies, and
wherein the white LED module further comprising a resin encapsulant containing the red phosphor for encapsulating the blue LED chip.

11. The white LED module according to claim 1, wherein the green light source comprises a green phosphor and the red light source comprises a red LED chip.

12. The white LED module according to claim 11, wherein the blue and red LED chips are mounted directly on the circuit board, and
wherein the white LED module further comprising a resin encapsulant containing the green phosphor for encapsulating both of the blue and red LED chips.

13. The white LED module according to claim 11, wherein the blue and red LED chips are mounted directly on the circuit board, and
wherein the white LED module further comprising a resin encapsulant containing the green phosphor for encapsulating only the blue LED chip.

14. The white LED module according to claim 11, further comprising at least one package body with a reflector cup disposed on the circuit board, wherein the blue and red LED chips are mounted in the reflector cup of the at least one package body.

15. The white LED module according to claim 14, wherein the blue and red LED chips are mounted together in the reflector cup of the package body, and
wherein the white LED module further comprising a resin encapsulant containing the green phosphor for encapsulating both of the blue and red LED chips.

16. The white LED module according to claim 14, wherein the at least one package body comprises two package bodies with each of the blue and red LED chips separately mounted in the reflector cup of each of the package bodies, and
wherein the white LED module further comprising a resin encapsulant containing the green phosphor for encapsulating the blue LED chip.

17. The white LED module according to claim 1, wherein the green light source comprises a green phosphor and the red light source comprises a red phosphor.

18. The white LED module according to claim 17, wherein the blue LED chip is mounted directly on the circuit board, and
wherein the white LED module further comprising a resin encapsulant containing the red and green phosphors for encapsulating the blue LED chip.

19. The white LED module according to claim 17, further comprising a package body with a reflector cup mounted on the circuit board, wherein the blue LED chip is mounted in the reflector cup of the package body, and
wherein the white LED module further comprising a resin encapsulant containing the green and red phosphors for encapsulating the blue LED chip.
